(19) United States
(12) Patent Application Publication
(10) Pub. No.: US 2024/0365529 A1
(43) Pub. Date: Oct. 31, 2024

(54) SEMICONDUCTOR STRUCTURE AND METHOD FOR MANUFACTURING THE SAME

(71) Applicant: Winbond Electronics Corp., Taichung City (TW)

(72) Inventor: Hsuan-Tung CHU, Tainan City (TW)

(21) Appl. No.: 18/632,669

(22) Filed: Apr. 11, 2024

(30) Foreign Application Priority Data
Apr. 25, 2023 (TW) 112115328

(51) Int. Cl. H10B 12/00

(52) U.S. Cl. CPC H10B 12/05; H10B 12/485; H10B 12/315

(57) ABSTRACT

A method for manufacturing a semiconductor structure including performing a first etching process on the substrate to form a first trench, and conformally forming a conformal layer on the surface of the first trench. The method further includes performing a second etching process on the substrate along the first trench to form a second trench below the first trench, wherein in the second etching process, the conformal layer has greater etch resistance than the substrate such that the top width of the second trench is greater than the bottom width of the first trench.

### CROSS REFERENCE TO RELATED APPLICATIONS

This application claims priority of Taiwan Patent Application No. 112115328 filed on Apr. 25, 2023, the entirety of which is incorporated by reference herein.

### BACKGROUND OF THE INVENTION

### Field of the Invention

The present disclosure relates to a semiconductor process technology, and in particular to the active region of the semiconductor structure and method of manufacturing the same.

### Description of the Related Art

As the critical dimensions of semiconductor devices gradually shrink, the lithography and etching processes become increasingly difficult. For example, in order to define active regions in a semiconductor substrate, lithography and etching processes are performed on the semiconductor substrate to form isolated structure trenches with high aspect ratios in one step. However, the etching rate difference between a region with relatively high-density mask patterns and a region with relatively low-density mask patterns leads to the etching loading effect, which results in tapering profiles partially in the active regions and damages the line width dimensions of the active regions. As a result, in a memory device, a short circuit may easily occur between the subsequently formed storage node contact structure and the bit line contact structure, thereby affecting the electrical performance of the memory device.

Therefore, the industry still needs to improve the method of manufacturing semiconductor devices to improve the yield of the semiconductor devices.

### BRIEF SUMMARY OF THE INVENTION

The embodiments of the present disclosure provide solutions to improve the short circuit problem between the storage node contact structure and the bit line contact structure, thereby improving the electrical performance of the memory device.

An embodiment of the present disclosure provides a method of manufacturing a semiconductor structure, comprising performing a first etching process on a substrate to form a first trench. The method further comprises conformally forming a conformal layer on the surface of the first trench. The method further comprises performing a second etching process on the substrate along the first trench to form a second trench below the first trench. During the second etching process, the conformal layer has greater etch resistance than the substrate, such that the top width of the second trench is greater than the bottom width of the first trench.

Another embodiment of the present disclosure provides a semiconductor structure, comprising a substrate. The substrate comprises a plurality of first active regions. Each of the first active regions has an upper portion and a lower portion supporting the upper portion. The bottom width of the upper portion is greater than the top width of the lower portion. Each of the first active regions has a hammer-shaped profile. The semiconductor structure further comprises a trench isolation structure disposed between adjacent first active regions.

The embodiments of the present disclosure are able to maintain the desired line width of the active regions by dividing the etching process for forming the active regions into two etching processes and cooperating with the formation of the conformal layer. In addition, the hammer-shaped active regions formed by the method may prevent the active regions from being adversely remaining during the subsequent etching process to form the bit line contact structure. This reduces the possibility of the short-circuiting between the bit line contact structure and the subsequent formation of the storage node contact structure, and improves the yield and performance of the memory devices.

### BRIEF DESCRIPTION OF THE DRAWINGS

FIGS. 1 to 8 illustrate cross-sectional views at various fabrication stages of manufacturing the semiconductor structure according to one embodiment of the present disclosure; and

FIG. 9 illustrates a top view of the semiconductor structure according to one embodiment of the present disclosure.

### DETAILED DESCRIPTION OF THE INVENTION

The following disclosure provides many different embodiments for implementing different features of the invention. Specific examples of components and arrangements are described below to simplify the present disclosure. These are merely examples and are not intended to be limiting. For example, the formation of a first feature over or on a second feature in the description that follows may include embodiments in which the first feature and the second feature are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, when a number or a range of numbers is described with “about,” “approximate,” and the like, the term is intended to encompass numbers that are within a reasonable range considering variations that inherently arise during the manufacturing process, as understood by one of ordinary skill in the art. For example, the number or range of numbers encompasses a reasonable range including the number described, such as within +/−10% of the number described, based on known manufacturing tolerances associated with manufacturing a feature having a characteristic associated with the number.

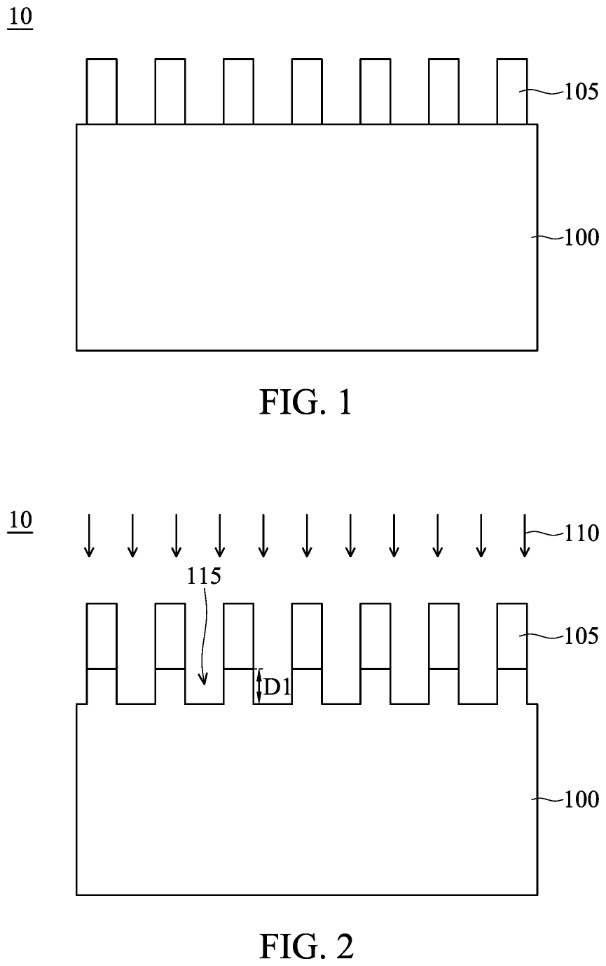

FIGS. 1 to 7 illustrate cross-sectional views at various fabrication stages of manufacturing the semiconductor structure 10 according to the embodiments of the present disclosure. First, referring to FIG. 1, a patterned mask 105 is formed on a substrate 100. In some embodiments, the substrate 100 may be elemental semiconductor substrate, such as silicon substrate or germanium substrate; a compound semiconductor substrate, such as a silicon carbide (SiC), gallium arsenide (GaAs), indium arsenide (InAs), or indium phosphide (InP) substrate; or an alloy semiconductor substrate, such as SiGe, SiGeC, GaAsP, or GaInP. In other embodiments, the substrate 100 may be a semiconductor-on-insulator (SOI) substrate. The above semiconductor-on-insulator substrate may include a substrate, a buried oxide layer disposed on the above substrate, and a semiconductor layer disposed on the above buried oxide layer.

The patterned mask 105 is used to define active regions on the substrate 100 that is subsequently formed. In some embodiments, the patterned mask 105 is a spacer pattern formed by the multiple patterning process, such as self-aligned double-patterning or self-aligned quadruple-patterning process to form the patterned mask 105.

In the embodiment of forming the patterned mask 105 using the multiple patterning process, a mandrel layer (not shown) may be formed first on the substrate 100, and a photoresist pattern is formed on the mandrel layer by photolithography and etching processes. An etching process is then performed to transfer the photoresist pattern to the mandrel layer to form a patterned mandrel. Subsequently, the spacers are formed on a plurality of opposing sidewalls of the patterned mandrel and the patterned mandrel is removed to form the patterned mask 105. In some embodiments, the patterned mandrel may be deposited by, for example, chemical vapor deposition (CVD), atomic layer deposition (ALD), or a combination thereof. The spacer material layer is then etching-back until the top surface of the patterned mandrel is exposed to form the spacers on the opposing sidewalls of the patterned mandrel. In some embodiments, the above etching-back process may include an anisotropic etching process such as reactive ion etching (RIE) process, plasma etching, inductively coupled plasma (ICP) etching, or dry etching of a combination thereof. In some embodiments, an etching process, a stripping process, an ashing process, or a combination thereof may be used to remove the above patterned mandrel. In some embodiments, the material of the above patterned mandrel may include carbon, silicon nitride (SiON), bottom anti-reflective coating (BARC), or a combination thereof. In other embodiments, the patterned mask 105 may use a photoresist layer formed by, for example, a spin-on coating process, where the photoresist layer is formed into a photoresist pattern by a photolithography process.

Referring next to FIG. 2, in some embodiments, a first etching process 110 is performed on the substrate 100 using the patterned mask 105 as a mask to form the first trench 115 in the substrate 100. The first etching process 110 is used to etch the portion of the substrate 100 that is not covered by the patterned mask 105. In some embodiments, the first etching process 110 may include an anisotropic etching process. In some preferred embodiments, the depth D1 of the first trench 115 may range from 3% to 13% relative to the depth of the final formed trench. In this way, the process is easier and the residual material of the first active region 135 in the subsequently formed third trench 150 is more effectively avoided, thereby more effectively avoiding the short-circuiting between the bit line contact structure 160 and the storage node contact structure 175.

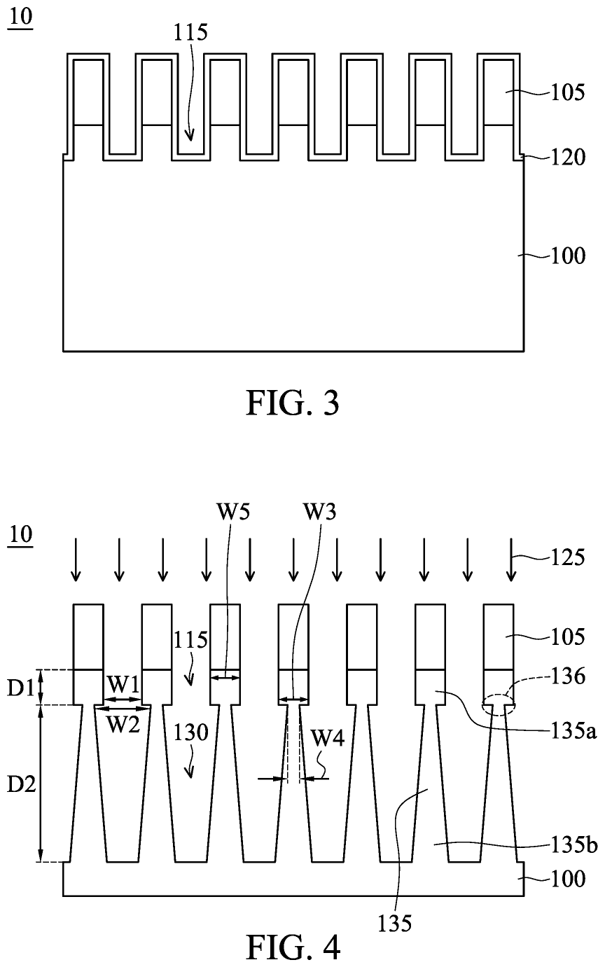

Referring to FIG. 3, in some embodiments, a conformal layer 120 is conformally formed on the surface of the first trench 115, such that the sidewalls and bottom of the first trench 115 are covered by the conformal layer 120. In some embodiments, the conformal layer 120 is used as an anti-etching layer that slows down the etching of the substrate 100 during the subsequent second etching process 125, as will be described hereinafter. In some embodiments, the conformal layer 120 further covers the top surface and sidewalls of the patterned mask 105. In some embodiments, the conformal layer 120 may be formed by chemical vapor deposition, atomic layer deposition, or a combination thereof. In other embodiments, the conformal layer 120 may be formed by a thermal oxidation process. In some embodiments, the material of the conformal layer 120 includes silicon oxide. In some preferred embodiments, the thickness of the conformal layer 120 may range from about 5 nm to about 10 nm to effectively protect the sidewalls of the first trench 115 while allowing for ease of process for the subsequent second etching process 125.

Referring to FIG. 4, in some embodiments, after forming the conformal layer 120, a second etching process 125 is performed on the substrate 100 along the first trench 115 to form a second trench 130 below the first trench 115. In the second etching process 125, due to the material differences, the conformal layer 120 has higher etching resistance than the substrate 100, such that the top width W2 of the second trench 130 is greater than the bottom width W1 of the first trench 115. More specifically, in some embodiments, the second etching process 125 is performed using the anisotropic etching, i.e., the etching rate of the second etching process 125 on the bottom of the first trench 115 is greater than the etching rate on the sidewalls of the first trench 115. By forming the conformal layer 120 on the sidewalls and bottom of the first trench 115 with a smaller etch selectivity ratio than the substrate 100, the etching to the sidewalls of the first trench 115 by the second etching process 125 may be further reduced. That is, the second etching process 125 etches the substrate 100 preferentially instead of the conformal layer 120, so that the top width W2 of the second trench 130 is greater than the bottom width W1 of the first trench 115. In some embodiments, the second etching process 125 is similar to the first etching process 110. That is, the second etching process 125 may have the same etchant, process temperature, and other process conditions as the first etching process 110, but the difference is that the process time of the first etching process 110 is less than the process time of the second etching process 125.

Continuing referring to FIG. 4, after the second etching process 125 is performed, a plurality of first active regions 135 are formed in the substrate 100, and each of the first active regions 135 includes an upper portion 135a defined by the first trench 115 and a lower portion 135b defined by the second trench 130. In some embodiments, the lower portion 135b of each of the first active regions 135 supports the upper portion 135a of each of the first active regions 135. In some embodiments, the bottom width W3 of the upper portion 135a of the first active region 135 is greater than the top width W4 of the lower portion 135b of the first active region 135 due to the previously described difference in etching rate, and the first active region 135 is hammer-shaped in the cross-sectional view. In other words, the first active region 135 has a relatively narrow neck 136. In some embodiments, the width of the lower portion 135b of the first active region 135 is tapered from bottom to top because the lateral etching intensity decreases with the etching depth. It should be noted that the height of the upper portion 135a of the first active region 135 is dependent on the depth D1 of the first trench 115, i.e., the height of the upper portion 135a of the first active region 135 may be controlled by controlling the first etching process 110 according to different design requirements. In some embodiments, the thickness of the conformal layer 120 may be selected such that the conformal layer 120 is removed together during the second etching process 125 to expose the sidewalls of the upper portion 135a of the first active region 135, and/or an additional etching processes may be performed after the second etching process 125 to remove the conformal layer 120. In some embodiments, the top width W5 of the upper portion 135a of the first active region 135 is equal to the bottom width W3 of the upper portion 135a of the first active region 135. In some embodiments, the ratio of the depth D1 of the first trench 115 to the depth D2 of the second trench 130 is from about 3% to about 13%. After forming the first active region 135, the semiconductor process such as various deposition, photolithography process, etching process, etc. may be continued to form other related components of the memory device, as described hereinafter.

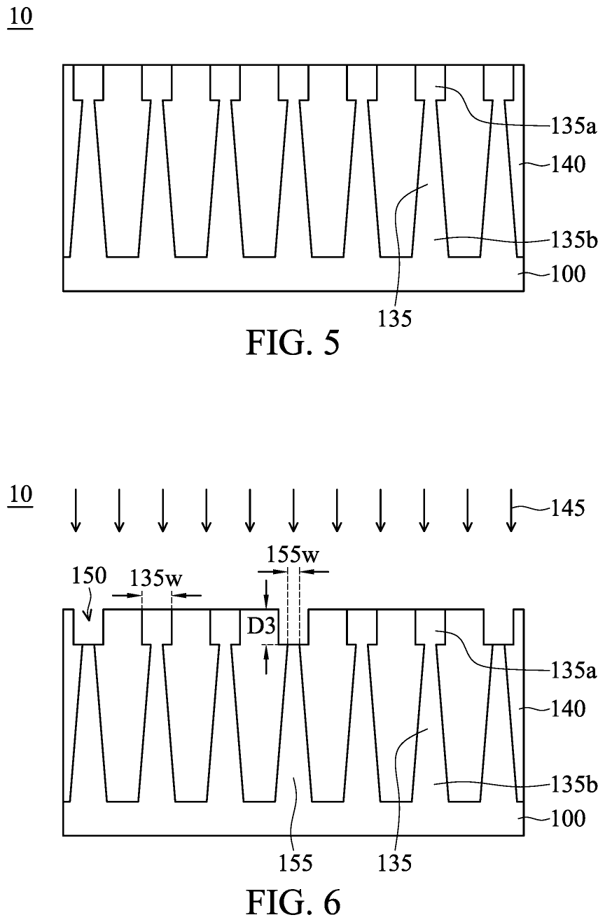

Referring to FIG. 5, after forming the first active region 135, the patterned mask 105 is removed. In some embodiments, after removing the patterned mask 105, the first trench 115 and the second trench 130 are filled with dielectric material and planarized to form a trench isolation structure 140. In some embodiments, the material of the trench isolation structure 140 may include silicon oxide, silicon nitride, high-density plasma (HDP) oxide, low-k dielectric material, spin-on coating glass, or other known insulating material, or a combination thereof. In some embodiments, the trench isolation structure 140 may be a shallow trench isolation (STI) structure.

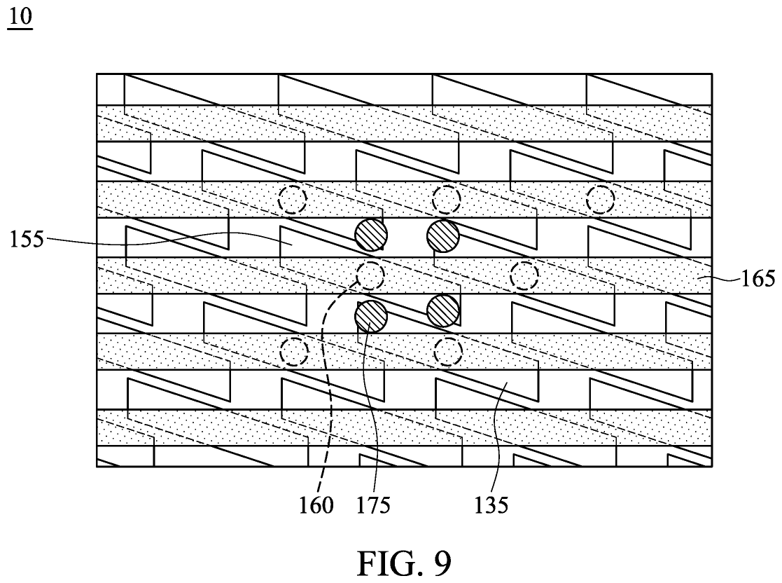

Referring to FIG. 6, a third etching process 145 is then performed on at least one upper portion 135a of the first active region 135 to form the third trench 150, and leaves at least a portion of the lower portion 135b of the first active region 135 below the third trench 150 as the second active region 155. It is noted that although in the cross-sectional view of FIG. 6, the second active region 155 is shown as consisting of only the lower portion 135b, the top view of FIG. 9 shows that the third trench 150 is actually a hollow hole in the upper portion 135a. That is, the second active region 155 may still have a portion outside of the above hollow hole corresponding to the upper portion 135a of the first active region 135. For simplicity, the mask defining the third trench 150 is not shown in FIG. 6. In some embodiments, the depth D3 of the third trench 150 may be greater than or equal to the depth D1 of the first trench 115, which facilitates the etching of the third trench 150. This avoids undesired upper portions 135a remaining in the second active region 155, and reduces the possibility of subsequent formation of bit line contact structures 160 short-circuiting with the adjacent storage node contact structures 175. In other words, the etching of the upper portion 135a by the third etching process 145 may be effectively improved by controlling the position of the neck 136 of the hammer-shaped first active region 135, so that the third trench 150 exposes the reduced horizontal area of the first active region 135. In some embodiments, similar to the lower portion 135b of the first active region 135, the width of the second active region 155 tapers from bottom to top. In the cross-sectional view of FIG. 6, the second active region 155 may be considered as the first active region 135 with the upper portion 135a removed, so that the top width 135w of the upper portion 135a of the first active region 135 is greater than the top width 155w of the second active region 155. In some embodiments, as previously described, the depth D3 of the third trench 150 may be greater than or equal to the depth D1 of the first trench 115, i.e., the top surface of the second active region 155 may be lower than or level with the top surface of the lower portion 135b of the first active region 135.

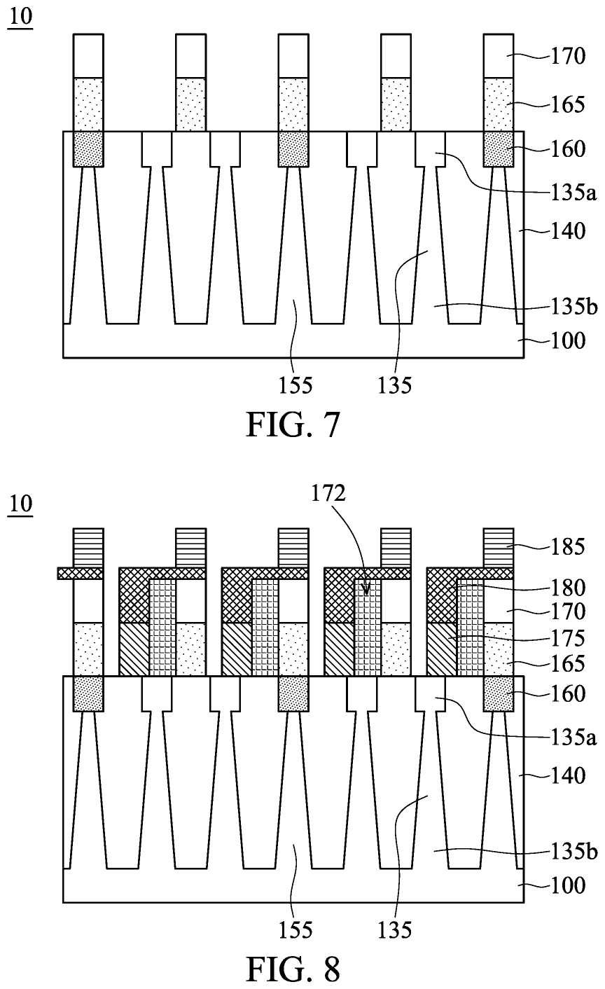

Referring to FIG. 7, the third trench 150 is filled with conductive material to form the bit line contact structure 160. Next, a bit line structure 165 is formed on the bit line contact structure 160 and a cap layer 170 is formed on the bit line structure 165 to protect the bit line structure 165. The bit line contact structure 160 may protrude from the substrate 100, and spacers can be further formed on the sidewalls of the bit line contact structure 160 to reduce electrical interference between the bit line contact structure 160 and the subsequently formed storage node contact structure 175. In the present embodiment, the top surface of the bit line contact structure 160 is level with the top surface of the upper portion 135a of the first active region 135. In some embodiments, the bit line structure 165 may include a barrier layer formed on the bit line contact structure 160 and bit lines formed on the barrier layer (not shown). In some embodiments, the material of the bit line contact structure 160 may include titanium nitride (TiN), tantalum nitride (TaN), tungsten nitride (WN), titanium aluminum nitride (TiAlN), similar materials, or a combination thereof. In some embodiments, the material of the above barrier layer may include titanium (Ti), titanium nitride (TiN), titanium oxide (TiO), tantalum (Ta), tantalum nitride (TaN), tantalum oxide (TaO), a similar material, or a combination thereof. In some embodiments, the material of the above bit lines may include a conductive material such as doped or undoped polycrystalline silicon (poly-Si), a metal, a similar material, or a combination thereof. In some embodiments, the material of the cap layer 170 may include silicon oxide (SiO), silicon nitride (SiN), silicon nitride (SiON), silicon carbide (SiC), silicon nitrogen carbide (SiCN), other similar materials, or a combination thereof.

Referring to FIG. 8, in some embodiments, after forming the cap layer 170, a storage node contact structure 175 is formed on each first active region 135. A landing pad 180 is then formed on the storage node contact structure 175, and a capacitive structure 185 is formed over the storage node contact structure 175. In some embodiments, a spacer 172 may be further formed on the sidewalls of the bit line structure 165 and the cap layer 170 to reduce electrical interference between the bit line contact structure 160 and the storage node contact structure 175. It is noted that in some embodiments, since the first active region 135 is hammer-shaped, i.e., the upper portion 135a of the first active region 135 is protected by the conformal layer 120 during the second etching process 125, the integrity of the upper portion 135a is maintained, which helps to improve the process margin of the storage node contact structure 175. In some embodiments, good bonding of the storage node contact structure 175 with the first active region 135 helps to improve the write recovery time (tWR) of the memory device. In some embodiments, the first active region 135 is electrically coupled to the capacitive structure 185 via the storage node contact structure 175 and the landing pad 180. In other words, the storage node contact structure 175 may be electrically connected to the capacitive structure 185 via the landing pad 180, which may be used to efficiently shift (e.g., stagger, adjust, modify) the storage node contact structure 175 to adapt to the position of the capacitive structure 185. The capacitive structure 185 may be used to store electrical charges representing programmable logic states. For example, a charged state of the capacitive structure 185 may represent a first logical state (e.g., logic 1), while an uncharged state of the capacitive structure 185 may represent a second logical state (e.g., logic 0). It should be understood that, for simplicity, FIG. 8 only schematically illustrates the spacer 172, the storage node contact structure 175, the landing pad 180, and the capacitive structure 185, and omits other related components such as the dielectric layer. In some embodiments, the material of the storage node contact structure 175 may include titanium nitride (TiN), tantalum nitride (TaN), tungsten nitride (WN), titanium aluminum nitride (TiAlN), other similar materials, or a combination thereof. In some embodiments, the material of the landing pad 180 may include conductive materials such as tungsten (W), titanium (Ti), nickel (Ni), platinum (Pt), gold (Au), alloys thereof, or other similar materials.

FIG. 9 illustrates a top view of the semiconductor structure 10 according to the embodiments of the present disclosure. In some embodiments, the first active region 135 and the second active region 155 are elongated structures in the top view. In some embodiments, the bit line contact structure 160 corresponds to the central position of the second active region 155 in the top view. In some embodiments, the storage node contact structure 175 corresponds to the end position of each of the first active regions 135 in the top view. The semiconductor structure 10 may be a memory device, such as a dynamic random access memory device (DRAM).

In summary, compared to conventional active region formation process, the embodiment of the present disclosure performs a first etching process to etch the substrate to a specific depth, and with the formation of a conformal layer, a plurality of hammer-shaped active regions are formed after the second etching process through the difference in etch selectivity ratio. By controlling the neck position of the hammer-shaped active region, the embodiment of the present disclosure may effectively improve the etching residue of the active region that may occur in the subsequent formation of the bit line contact structure. Further, the embodiment of the present disclosure may moderately slow down the etching of the upper portion of the active region by using the conformal layer to increase the process margin for the subsequent formation of the storage node contact structure. Thus, the various embodiments described herein offer several advantages over the existing art. It will be understood that not all advantages have been necessarily discussed herein, no particular advantage is required for all embodiments, and other embodiments may offer different advantages.

The present invention provides a semiconductor structure and method of manufacturing the same that improves the yield and performance of a semiconductor device. By improving the yield and performance, the present invention can reduce the number of defective devices that need to be discarded, thereby reducing electronic waste. Additionally, by improving the manufacturing process, the invention can potentially reduce the consumption of resources and energy, further contributing to the development of green semiconductor technology. Besides, the present invention is suitable for making miniaturized semiconductor devices, so as to increase the total number of dies on a wafer. Therefore, the production cost and energy consumption of manufacturing a single IC are reduced, and the production energy consumption of subsequent packaging is also reduced, thereby reducing carbon emissions in the process of producing a semiconductor device.

The scope of the present disclosure is not limited to the technical solutions consisting of specific combinations of the technical features described above, but should also cover other technical solutions consisting of any combinations of the technical features described above or their equivalent features, all of which are within the scope of the protection of the present disclosure.

What is claimed is:

1. A method of manufacturing a semiconductor structure, comprising:
performing a first etching process on a substrate to form a first trench;
conformally forming a conformal layer on a surface of the first trench; and
performing a second etching process on the substrate along the first trench to form a second trench below the first trench, wherein during the second etching process, the conformal layer has greater etch resistance than the substrate, such that a top width of the second trench is greater than a bottom width of the first trench.

2. The method as claimed in claim 1, wherein the second etching process forms a plurality of first active regions in the substrate, and each of the first active regions comprises:
an upper portion defined by the first trench; and
a lower portion defined by the second trench.

3. The method as claimed in claim 2, wherein a bottom width of the upper portion is greater than a top width of the lower portion, and wherein the first active regions have a hammer-shaped profile.

4. The method as claimed in claim 2, wherein a width of the lower portion of the first active regions tapers from bottom to top.

5. The method as claimed in claim 2, further comprising:
forming a patterned mask on the substrate prior to performing the first etching process on the substrate;
after the second etching process, removing the patterned mask;
after the removal of the patterned mask, filling the first trench and the second trench with a dielectric material to form a trench isolation structure;
performing a third etching process on at least one upper portion of the first active regions to form a third trench, and leaving at least one portion of the lower portion below the third trench as a second active region;
filling a conductive material into the third trench to form a bit line contact structure; and
forming a bit line structure on the bit line contact structure.

6. The method as claimed in claim 5, wherein a depth of the first trench is less than or equal to a depth of the third trench.

7. The method as claimed in claim 5, wherein a width of the second active region tapers from bottom to top.

8. The method as claimed in claim 5, further comprising:
forming a storage node contact structure on each of the first active regions;
forming a landing pad on the storage node contact structure; and
forming a capacitive structure over the storage node contact structure, wherein the storage node contact structure, the landing pad, and the capacitive structure are electrically connected.

9. The method as claimed in claim 5, wherein the conformal layer further covers a top surface and sidewalls of the patterned mask.

10. The method as claimed in claim 1, wherein the conformal layer is formed by an atomic layer deposition process, and a material of the conformal layer comprises silicon oxide.

11. The method as claimed in claim 1, wherein a ratio of a depth of the first trench to a depth of the second trench is 3% to 13%.

12. A semiconductor structure, comprising:
a substrate comprising a plurality of first active regions and a second active region, wherein each of the first active regions has an upper portion and a lower portion supporting the upper portion, wherein a bottom width of the upper portion is greater than a top width of the lower portion, and wherein each of the first active regions has a hammer-shaped profile; and
a trench isolation structure disposed between the adjacent first active regions, wherein the second active region is separated from the first active regions by the trench isolation structure, and wherein a top surface of the second active region is not greater than a top surface of the lower portion of the first active regions.

13. The semiconductor structure as claimed in claim 12, wherein a width of the lower portion of each of the first active regions and a width of the second active region taper from bottom to top.

14. The semiconductor structure as claimed in claim 12, wherein a top width of the upper portion of each of the first active regions is greater than a top width of the second active region.

15. The semiconductor structure as claimed in claim 12, further comprising:
a bit line contact structure disposed on the second active region; and
a bit line structure disposed on the bit line contact structure.

16. The semiconductor structure as claimed in claim 15, wherein a top surface of the bit line contact structure is level with a top surface of the upper portion of the first active regions.

17. The semiconductor structure as claimed in claim 15, further comprising:
a storage node contact structure disposed on the upper portion of each of the first active regions;
a landing pad disposed on the storage node contact structure; and
a capacitive structure disposed over the storage node contact structure, wherein each of the first active regions, the storage node contact structure, the landing pad, and the capacitive structure are electrically connected.

18. The semiconductor structure as claimed in claim 17, wherein each of the first active regions and the second active region is an elongated structure in a top view, wherein the bit line contact structure corresponds to a central position of the second active region in the top view, and wherein the storage node contact structure corresponds to an end position of each of the first active regions in the top view.

19. The semiconductor structure as claimed in claim 12, wherein a top width of the upper portion of each of the first active regions is equal to the bottom width of the upper portion of each of the first active regions.
